(19) United States
(12) Patent Application Publication
(10) Pub. No.: US 2025/0174514 A1
(43) Pub. Date: May 29, 2025

(54) POWER SEMICONDUCTOR SWITCHING MODULE

(71) Applicant: NexFi Technology Inc., Suita-shi, Osaka (JP)

(72) Inventors: Satoshi TANIMOTO, Suita-shi, Osaka (JP); Takashi NAKAMURA, Suita-shi, Osaka (JP); Kei NISHIOKA, Suita-shi, Osaka (JP); Toshio HANADA, Suita-shi, Osaka (JP); Takafumi OKUDA, Suita-shi, Osaka (JP)

(21) Appl. No.: 18/841,823

(22) PCT Filed: Feb. 21, 2023
(86) PCT No.: PCT/JP2023/006298

§ 371 Date: Aug. 27, 2024

(30) Foreign Application Priority Data
Mar. 22, 2022 (JP) 2022-045899

(51) Int. Cl. H01L 23/373; H01L 23/00; H01L 23/538; H01L 25/07

(52) U.S. Cl. CPC H01L 23/3735; H01L 24/32; H01L 25/072; H01L 23/538; H01L 2224/32245

(57) ABSTRACT

Provided is a thermal circuit composed of unit cells Uᵢⱼ includes a first heat flow path composed of thermal resistances from a heat source to the lower surfaces of chip metal conductors Bᵢⱼ, and a second heat flow path composed of thermal capacitances branching from the first heat flow path to the atmosphere on each surface side, the thermal capacitances branching at the surface of each of power semiconductor SW chips Sᵢⱼ, die attaches Dᵢⱼ, and the chip metal conductors Bᵢⱼ. With respect to the heat generation of the power semiconductor SW chips Sᵢⱼ at the time of single-pulse current-carrying in an ms range, the thermal impedance of the thermal circuit is set so that the power semiconductor SW chips Sᵢⱼ can be maintained at or below a rated temperature by heat dissipation through the entire thermal circuit of the first heat flow path and the second heat flow path.

### TECHNICAL FIELD

The present invention relates to a single-pulse power semiconductor switching module in which a plurality of power semiconductor switch chips are mounted.

### BACKGROUND ART

Hereinafter, for the sake of simplicity, a time range of 1 ms (milliseconds) or more and less than several tens of ms will be referred to as an “ms range”, a power semiconductor switching module will be abbreviated as a “PSM”, and a switch will be abbreviated as a “SW” as appropriate.

A single-pulse PSM refers to a PSM that is normally in a breaking state, but has the function and purpose of being in a current-carrying state for an extremely short period in the ms range at certain times (for example, in the event of an abnormality). A typical application of the single-pulse PSM is a semiconductor breaker path in a high-power hybrid DC circuit breaker that is composed of a mechanical SW path and the semiconductor breaker path (Non-Patent Literature 1). The single-pulse PSM is applicable not only to high power application but also to medium and small power application, furthermore and also to short-time current-carrying AC power application.

The power semiconductor switching module of the present invention includes, in addition to the above-mentioned single-pulse PSM, a power semiconductor switching module that performs both single-pulse current-carrying and non-single-pulse current-carrying.

Conventional single-pulse PSMs have diverted a non-single-pulse current-carrying power semiconductor switching modules (for example, Patent Literature 1).

Let's roughly describe the configuration of a conventional single-pulse PSM. Power semiconductor SW unit cells, in which a predetermined power semiconductor SW chip (power MOSFET, IGBT, diode, and the like) is bonded by die attach such as soldering onto a thin chip metal conductor placed and bonded on the upper surface of an insulating substrate, are arranged on one metal base plate, connected in parallel in a number that satisfies a required current capacity, and connected in series in a number that satisfies a required withstand voltage.

Parallel connection of the power semiconductor SW unit cells is usually achieved by using a common chip metal conductor. On the other hand, series connection is achieved between a pair of adjacent unit cells by connecting the semiconductor upper electrode of the higher-potential side unit and the chip metal conductor of the lower-potential side unit with an interconnect such as a bonding wire.

### CITATION LIST

### Patent Literature

Patent Literature 1: Japanese Patent Application Laid-Open No. 2006-216730

### Non-Patent Literature

Non-Patent Literature 1: Toshiaki Matsumoto, Naotaka lio, “Large Capacity DC Circuit Breaker (DCCB)” Journal of the Institute of Electrical Engineers of Japan, Vol. 137, No. 11, (2017), pp. 757-760

### SUMMARY OF INVENTION

### Technical Problem

A common configuration is that the power semiconductor SW unit cells have a common insulating substrate (integrated), and each chip metal conductor is disposed on this insulating substrate. In some cases, the metal base plate can also be omitted. The thickness of the insulating substrate is determined in consideration of the voltage and ampacity controlled by the PSM, the strength of surge voltage caused by switching, mechanical strength, or heat dissipation. In general, the larger the electric power handled, the thicker the insulating substrate becomes.

An object of the present invention is to provide a single-pulse power semiconductor switching module that can be downsized and reduced in cost.

### Solution to Problem

The present invention is a power semiconductor switching module including an insulating substrate, a chip metal conductor stacked on an upper surface side of the insulating substrate, a plurality of power semiconductor SW chips, and a die attach interposed between the chip metal conductor and each of the power semiconductor SW chips, in which each of the power semiconductor SW chips, the die attach under a lower surface side of the power semiconductor SW chip, and the chip metal conductor under a lower side of the die attach constitutes a thermal circuit that releases heat from a heat source of each of the power semiconductors SW chip to the atmosphere, each thermal circuit includes a first heat flow path composed of thermal resistances from each heat source to a lower surface of the chip metal conductor, and a second heat flow path composed of thermal capacitances branching from the first heat flow path to the atmosphere on each surface side, the thermal capacitances branching at the surface of each of the power semiconductor SW chips, the die attaches, and the chip metal conductors, and with respect to heat generation of the power semiconductor SW chips at the time of single-pulse current-carrying in a predetermined ms range, regardless of whether or not heat dissipation through only the first heat flow path is able to maintain the power semiconductor SW chips at or below a maximum rated temperature, a transient thermal impedance of the thermal circuit is set so that the power semiconductor SW chips are maintained at or below the maximum rated temperature by heat dissipation through the entire thermal circuit of the first heat flow path and the second heat flow path.

### Effect of the Invention

According to the present invention, since the power semiconductor switching module has an adequate configuration based on a thermal circuit that focuses on transient thermal impedance with respect to heat generation of the power semiconductor SW chip when carrying load current in the ms range, it is possible to reduce the size and cost of the power semiconductor switching module.

### BRIEF DESCRIPTION OF DRAWINGS

FIG. 1 is a plan view of a single-pulse current carrying power semiconductor switching module (single-pulse PSM) according to the present invention.

FIG. 2 is a circuit notation view of a single-pulse PSM in FIG. 1.

FIG. 3 is a vertical cross-sectional view of an arbitrary power semiconductor SW unit cell Uᵢⱼ of the single-pulse PSM in FIG. 1.

FIG. 4 is a thermal circuit diagram of the unit cell U₂₂.

FIG. 5 is a view collectively showing the vertical and horizontal dimensions of respective unit cells for a PSM of Example 1 and a PSM of Comparative Examples 1-1 and 1-2.

FIG. 6 is a table showing thermophysical constants of materials for each portion of PSMs used in Example 1 and Comparative Examples 1-1 and 1-2.

FIG. 7 is a table showing values of a steady-state heat capacitor Cₙ and a steady-state heat resistor Rₙ of each portion of PSMs, which are obtained by applying the values in the table of FIG. 6 to an extended one-dimensional heat conduction model.

FIG. 8 is a graph showing the results of simulating a transient thermal impedance characteristic Z_{j-c}(t) in the ms range by performing numerical calculations by substituting the values in the table of FIG. 7 into the thermal circuit model of FIG. 4.

FIG. 9 is a graph plotting Z_{j-c} after 1 ms and 10 ms as a function of t_{SiC}.

FIG. 10 is a graph plotting the relationship between the transient thermal impedance Z_{j-c} after 1 ms and 10 ms and t_{DA}.

FIG. 11 is a graph showing the relationship between the transient thermal impedance Z_{j-c} after 1 ms and 10 ms and a thickness t_{Cu} of a chip metal conductor (Cu) Bᵢⱼ-FIG. 12 is a graph showing the relationship between the transient thermal impedance Z_{j-c} after 1 ms and 10 ms and the outer edge increment of the chip metal conductor (Cu) Bᵢⱼ, Al_{Cu}.

FIG. 13 is a graph showing the transient thermal impedance characteristics Z_{j-c}(t) of Example 2 and Comparative Example 2 in the ms range.

FIG. 14 is a graph showing the transient thermal impedance characteristics Z_{j-c}(t) of Example 3 and Comparative Example 3 in the ms range.

FIG. 15 is a graph showing the transient thermal impedance characteristics Z_{j-c}(t) of Example 4 and Comparative Example 4 in the ms range.

FIG. 16 is a graph showing the transient thermal impedance characteristics Z_{j-c}(t) of Example 5 and Comparative Example 5 in the ms range.

FIG. 17 is a schematic view of a DC power supply system as an application example of a DC circuit breaker equipped with the single-pulse PSM of FIG. 1.

FIG. 18 is a cross-sectional view of a power semiconductor SW unit cell U′ of a single-pulse PSM, which is the basis for problem extraction of the present invention.

FIG. 19 is a graph showing the results of a transient thermal analysis performed by the present inventors on the single-pulse PSM (Comparative Example 1-1) of FIG. 18.

### DESCRIPTION OF EMBODIMENTS

Hereinafter, an embodiment of the present invention will be described. It goes without saying that the present invention is not limited to the embodiment. The components common to a plurality of embodiments are denoted by the same reference numerals throughout the drawings.

### (Creation of Problem)

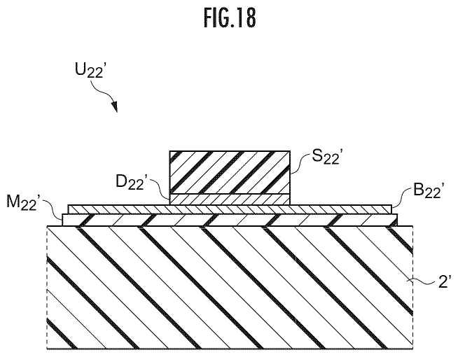

First, extraction of the problem to be solved by the present invention will be described. FIG. 18 is a cross-sectional view of a power semiconductor SW unit cell U₂₂′ in the conventional single-pulse PSM, which is the basis for problem extraction of the present invention.

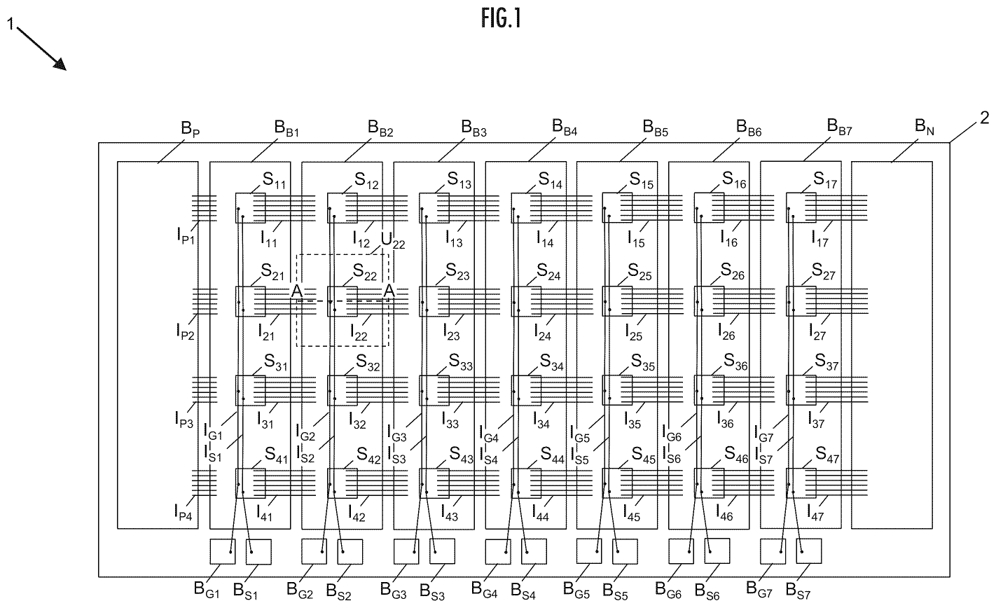

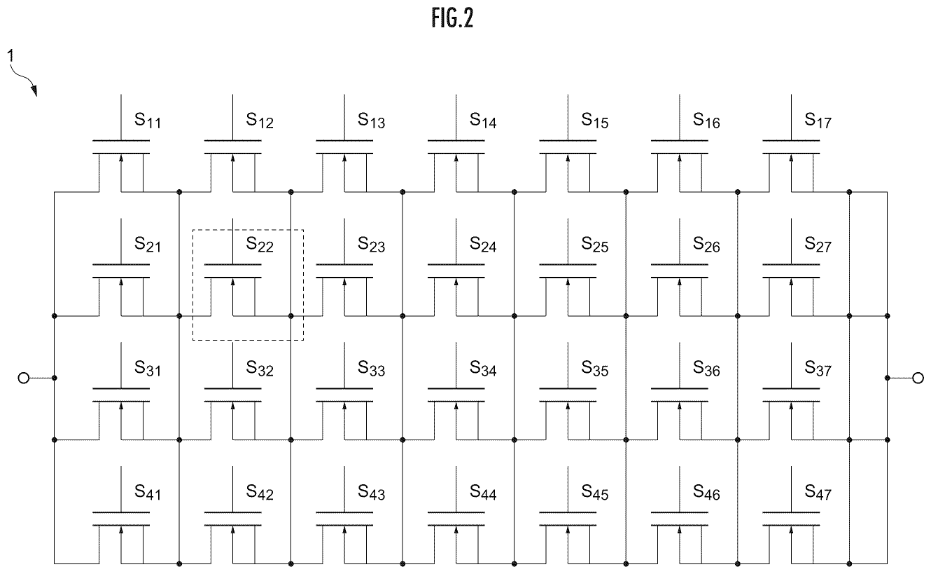

This power semiconductor SW unit cell U₂₂′ is assumed to be used in a standard single-pulse PSM with a withstand voltage of 7 kV or more and a current capacity of 350 A class. Further, an example is assumed in which the power semiconductor SW unit cells U₂₂′ are arranged in 4 parallel×10 series (the specific arrangement pattern will be described later with reference to FIG. 1) to configure the PSM.

S₂₂′ is a SiC power MOSFET (thickness: 0.35 mm) chip as a power semiconductor SW with a rating of 1200V and 90 A or more, B₂₂′ is a chip metal conductor made of pure copper, D₂₂′ is a tin-silver-copper solder based die attach (for example, SAC305, thickness: 0.1 mm), 2′ is an alumina insulating substrate (thickness: 5 mm), and M₂₂′ is a heat transfer bonding material for thermally and mechanically bonding the chip metal conductor B₂₂′ and the alumina insulating substrate 2′, such as a silicone based thermally conductive sheet (thickness: 0.1 mm).

When an output gate signal (voltage) is simultaneously applied to all power semiconductor SW chips from an attached drive circuit, the PSM is in a current-carrying state, and when the output gate signal (voltage) is removed, the PSM is in a breaking state.

As is well known, in a non-single-pulse type PSM, efforts to reduce the number of power semiconductor SW chips and the size (area) of the PSM are emphasized under the restriction that all the power semiconductor SW chips mounted inside are not used at temperatures exceeding a maximum rated temperature T_{jMAX}. This is to improve the driving performance and marketability (cost performance) of the PSM. For this reason, there is a strong demand for increasing the current that can flow per one power semiconductor SW1 chip (=chip current rating) during operation. This requirement also applies to the single-pulse PSM.

A measure to reliably meet this requirement is to construct a structure in which Joule heat generated in the power semiconductor SW chip is efficiently dissipated to the outside of the power semiconductor SW unit cell (=outside the module). Specifically, the objective is to effectively reduce the sum R_{j-c} of the steady-state thermal resistances of the element members in the heat dissipation path from the front surface of the power semiconductor SW chip to the back surface of the insulating substrate or the metal base plate in the power semiconductor SW unit cell.

Since the main components that account for the steady-state thermal resistance R_{j-c} of the module are the chip metal conductor, the insulating substrate, the metal base plate, and the bonding material that bonds these three element members, how to reduce the thermal conductivity and thickness of these materials has been a major concern in the conventional non-single-pulse type PSM (=standard PSM) thermal design.

Even in the PSM for single-pulse power application in the ms range, the steady-state thermal resistance R_{j-c} has been traditionally regarded as an important index of heat dissipation, and therefore thermal designs have been made to lower R_{j-c}. This means that it was recognized that by lowering R_{j-c}, the transient thermal impedance Z_{j-c}(t) in the ms range (in this specification, impedance is a concept that includes both resistance and reactance) would be similarly reduced. Hereinafter, simply “transient thermal impedance” refers to the transient thermal impedance Z_{j-c} of the surface of the power semiconductor SW chip viewed from the back surface of the unit cell.

After careful consideration, the present inventors found that in a single-pulse PSM based on such conventional thermal design concepts, the following problem (issue) was created.
(1) Reduction of transient thermal impedance in the ms range is insufficient.
(2) The chip current density cannot be increased.
(3) As a result of 1 and 2 above, downsizing and low cost of the PSM cannot be achieved.

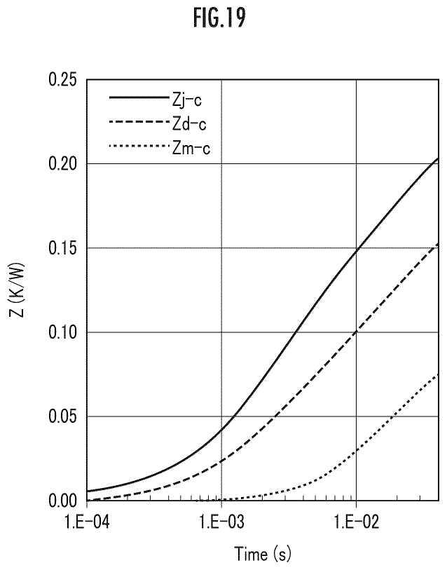

FIG. 19 shows the results of a transient thermal analysis performed by the present inventors on the single-pulse PSM (Comparative Example 1-1) of FIG. 18. This graph shows temporal changes in the transient thermal impedance Z_{j-c} of Comparative Example 1-1, a transient thermal impedance Zac at the power semiconductor SW chip/die attach (Sᵢⱼ/Dᵢⱼ) interface of the same cell, and a transient thermal impedance Z_{m-c} at the die attach/chip metal conductor (Dᵢⱼ/Mᵢⱼ) interface.

The impedance (=resistance+reactance) on the vertical axis of the graph in each figure including FIG. 19 is an evaluation amount (see (Equation 1) to be described later) obtained by dividing a temperature difference with respect to the environmental temperature of the node of interest by a Joule heat generation PD (constant, unit W) of the power semiconductor SW chip, and the unit is K/W.

The present inventors focused on the thermal capacitance heat dissipation effect (intuitively, this corresponds to the heat storage effect) of the power semiconductor SW chip, die attach, and chip metal conductor, in addition to the transient thermal impedance Z_{j-c} of the surface of the power semiconductor SW chip viewed from the back side of the unit cell. Then, from the analysis results shown in FIG. 19, the insights about the transient thermal impedance Z_{j-c} of the PSM unit cell are as follows: 1) in the time range from 1 ms to around 5 ms, the main components are the thermal impedance of the power semiconductor SW chip and the thermal impedance of die attach, 2) when >5 ms, the thermal impedance component of the chip metal conductor is added to these main components. It is also found that in order to reduce the transient thermal impedance Z_{j-c} in the ms range, it is effective to first reduce the thermal impedance component of the power semiconductor SW chip and die attach, and then reduce the thermal impedance component of the chip metal conductor.

The present invention was conceived by the inventors of the present invention and was made through continuous efforts.

### EMBODIMENT

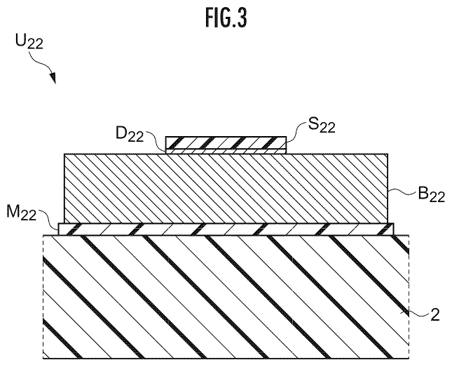

FIG. 1 is a plan view of a single-pulse current carrying power semiconductor switching module (single-pulse PSM) 1 according to the present invention, FIG. 2 is a circuit diagram of a single-pulse PSM 1, and FIG. 3 is a vertical cross-sectional view of an arbitrary power semiconductor SW unit cell (hereinafter, simply referred to as “unit cell”) Uᵢⱼ of the same single-pulse PSM1. In “Uᵢⱼ”, subscripts i and j mean the address (row i, column j) of the unit cell in FIGS. 1 and 2. The meanings of the subscripts i and j attached to the symbols of portions other than the unit cell are the same below.

The single-pulse PSM1 of the present invention shown in FIGS. 1 and 2 shows an example in which the unit cells Uᵢⱼ are connected in 7 in series×4 in parallel, but this series/parallel number is merely an example for convenience of description, and any combination of parallel number×series number may be used as long as the number of unit cells is 2 or more.

The basic structure of the unit cells Uᵢⱼ is basically the same. However, in the present invention, a modification in which different kinds of power semiconductor switches are mixed together is also possible. In such a case, the configurations of the dissimilar power semiconductor switch unit cells will be different. A case that often occurs in practice is when a power diode is placed in antiparallel with a power transistor. In such a case, for example, the power semiconductor switch of the unit cell Uᵢⱼ in the even-numbered i row is a power transistor, and the power semiconductor switch of the unit cell Uᵢⱼ in the odd-numbered i row is a power diode.

Turning to a detailed description of the structure, Sᵢⱼ is a thin power semiconductor SW chip bonded onto a thick chip metal conductor Bᵢⱼ via a thin die attach Dᵢⱼ. The chip metal conductors Bᵢⱼ having the same column number j are actually integrated as shown in FIG. 1 in order to connect the power semiconductor SW chips Sᵢⱼ in the same column in parallel and constitute of an integrated chip metal conductor B_{Bj}. Each metal conductor B_{Bj} (not shown) is bonded onto a common insulating substrate 2 via a heat transfer bonding material M_{Bj}.

B_{P} is a P-terminal metal conductor for attaching a P terminal (not shown) of the main circuit, B_{N} is an N-terminal metal conductor for attaching an N terminal (not shown) of the main circuit, and each B_{Gj} and B_{Sj} is a control terminal metal conductor for attaching an input terminal (not shown) of a signal line that controls turn-on/turn-off of the power semiconductor SW chip Sᵢⱼ of the j-row unit cell. The P-terminal metal conductor B_{P}, the N-terminal metal conductor B_{N}, and the control terminal metal conductors B_{Gj} and B_{Sj} are bonded onto the common insulating substrate 2 via a heat transfer bonding material (not shown), similarly to the chip metal conductor Bᵢⱼ.

Iᵢⱼ is a main circuit interconnect, made of thick Al (aluminum) bonding wire, for connecting in series the power semiconductor SW chip Sᵢⱼ and the right adjacent power semiconductor SW chip Sᵢ₍ⱼ₊₁₎. Each Iᵢⱼ connects the upper surface electrode of Sᵢⱼ to the chip metal conductor B_{B(j+1)} of the right adjacent unit cell. I_{Pi} is a main circuit interconnect, made of thick Al (aluminum) bonding wire, that connects the P-terminal metal conductor B_{P} and the first column chip metal conductor BB1 adjacent to the right. I_{Gj} and I_{Sj} are signal line interconnects, made of thin Al (aluminum) bonding wire, that connect the pair of control signal electrodes (gate electrode, Kelvin source electrode, or the like) of the chip metal conductors Bᵢⱼ arranged in the j column.

When configuring a single-pulse PSM in which the insulating substrate 2 is divided for some reason, as in Patent Literature 1, a common base metal substrate may be prepared and a plurality of divided insulating substrates 2 may be placed on the surface thereof.

The single-pulse PSM according to the embodiment shown in FIGS. 1 to 3 is optimized to effectively reduce transient thermal impedance in the ms range. Compared with the conventional single-pulse PSM, this optimization appears as a remarkable difference in the attributes of the power semiconductor SW chip Sᵢⱼ, the die attach Dᵢⱼ, and the chip metal conductor Bᵢⱼ.

The power semiconductor SW chip Sᵢⱼ is any semiconductor such as SiC, GaN, or Si. For example, a low-resistance power transistor such as a MOSFET or an IGBT, or a low-resistance power diode such as a pn diode or a Schottky diode can be used.

In order to reduce the transient thermal impedance of the PSM unit cell in the ms range, it is desirable that the thickness of the power semiconductor SW chip Sᵢⱼ is as thin as possible, with the lower limit being the power semiconductor SW effective device layer thickness, at most 0.25 mm or less, preferably 0.2 mm or less.

As is well known, the power semiconductor SW is formed on the surface layer of a semiconductor substrate. The effective device layer thickness refers to the thickness of this power semiconductor SW layer. As the thickness of the power semiconductor SW chip approaches the effective device layer thickness, the power semiconductor SW is not able to function as a SW, and therefore the thickness must be thicker than the effective device layer thickness. It is known that the effective device layer thickness tends to be thicker for semiconductor materials with smaller energy band gaps (or intrinsic breakdown electric fields).

Next, for the die attach Dᵢⱼ, a bonding material guaranteed to have low resistivity, such as solder (Sn—Ag—Cu based, Pb based, Sn—Cu based, Au based solder), sintered Ag paste, or sintered Cu paste, can be used. However, the material is not limited to these materials, and other low-resistivity materials may be used.

In order to achieve a reduction in the transient thermal impedance in the ms range, in the embodiment, it is desirable that the thickness of the die attach Dᵢⱼ is as thin as possible, 0.07 mm or less, preferably 0.05 mm or less. The practical lower limit of thickness is determined by the industrial stability and cost of the bonding technique.

Next, a base metal material exhibiting low resistance and good thermal conductivity can be used for the chip metal conductor Bᵢⱼ. Examples of such materials include Cu and Al, but other base metal materials may also be used. In order to improve the bonding with the die attach Dᵢⱼ, the surface of the chip metal conductor may be plated with Ni, Au, Ag, or Pt.

In order to reduce the transient thermal impedance of PSM (unit cell) in the ms range, in the present embodiment, the thickness of the chip metal conductor Bᵢⱼ is preferably at least 0.8 mm or more and 5 mm or less, more preferably 1.5 mm or more and 3 mm or less.

Further, in order to reduce the transient thermal impedance in the ms range, the outer edge of the chip metal conductor Bᵢⱼ is preferably larger than the outer edge of the power semiconductor SW chip Sᵢⱼ by an increment Δl (see FIG. 5) in the range of 1.1 mm to 5.1 mm, and more preferably larger by Δl=2.1 mm to 4.1 mm. When the vertical and horizontal lengths of the power semiconductor SW chip Sᵢⱼ are a and b, the vertical length of the chip metal conductor Bᵢⱼ is a+2Δl, and the horizontal length is b+241.

There are no major restrictions on the heat transfer bonding material Mᵢⱼ as long as the heat transfer bonding material Mᵢⱼ has normal heat conductivity, and the heat transfer bonding material Mᵢⱼ can be selected relatively freely from conventional heat transfer bonding materials. Applicable materials include silicone-based thermally conductive sheets and solders (Sn—Ag—Cu based, Pb based, and Sn—Cu-based). When using solder as the heat transfer bonding material, it is assumed that the surface of the insulating substrate 2 is metallized. There are no particularly strong requirements regarding the thickness of the heat transfer bonding material, and the thickness may be, for example, 0.1 mm to 0.3 mm.

Similarly to the conventional single-pulse PSM, an insulating substrate having the same specifications as the conventional PSM can be selected as the insulating substrate 2, in consideration of dielectric breakdown strength to ground and mechanical strength. For example, an insulating substrate made of alumina, which is an inexpensive material, can be used. In the single-pulse PSM of the present invention, there is no need to intentionally employ a silicon nitride substrate or an aluminum nitride substrate (both relatively expensive), which have higher thermal conductivity than an alumina insulating substrate.

Hereinafter, in order to confirm the effect of the single-pulse PSM of the embodiment of the present invention with respect to the conventional single-pulse PSM, by using some specific examples, the transient thermal impedance Z_{j-c} in the ms range of the conventional single-pulse PSM (comparison) and the single-pulse PSM of the present invention will be compared with each other. In order to make a comparison, here, the transient thermal impedance Z_{j-c} characteristic is simulated by applying an extended one-dimensional thermal conduction model in consideration of thermal spread and a ladder thermal circuit model.

A general description of thermal spreading will be added. In a thermal circuit with a stacked structure like the unit cell Uᵢⱼ, it is assumed that an upstream layered body Lₐ and a downstream layered body L_{b} are adjacent to each other in a heat flow direction, and the thermal conductivities of the layered bodies Lₐ and L_{b} are Ka and Kb, respectively, and the upper surface of the layered body Lₐ is in contact with a planar heating surface L₀ having a smaller area than the layered body Lₐ. The heat transmitted from the planar heating surface L₀ to the layered body Lₐ spreads in the radial direction in the layered body Lₐ. When it is assumed the thermal spreading angle of the heat on the surface of the layered body Lₐ is α, α is calculated as α=tan⁻¹ (Ka/Kb). The thermal spreading angle in the direction perpendicular to the thermal bonding surface of the planar heating surface L₀ and the layered body Lₐ is α=0°, and the thermal spreading angle in the direction parallel to the bonding surface (radial direction) is α=90°.

When the thermal spreading angle α is small and the thickness of the layered body Lₐ is relatively thin or the radial dimension of the layered body Lₐ is sufficiently larger than the planar heating surface L₀, the thermal conduction from the planar heating surface L₀ to the layered body Lₐ continues to spread to the layered body L₀ below the layered body Lₐ. On the other hand, when the thermal spreading angle α is large and the thickness of the layered body Lₐ is relatively thick or the radial dimension is not sufficiently larger than the planar heating surface L₀ in the layered body Lₐ, the heat conducted from the planar heating surface L₀ to the layered body Lₐ reaches the surface of the side surface of the layered body Lₐ at a predetermined depth, and at a depth below that, heat is conducted toward the layered body L_{b} without thermal spreading.

Thermal conduction inside each layered body is defined by a steady-state thermal resistance Rₙ, which will be described later, in each layered body. The amount of heat stored in each layered body is defined by the steady-state thermal capacitance Cₙ of each layered body, which will be described later.

Based on the above, a method of calculating the transient thermal impedance Z_{j-c} of the unit cell Uᵢⱼ will be described. First, the thermophysical constants and dimensions of each layer (that is, power semiconductor SW chip and die attach, chip metal conductor, heat transfer bonding material, insulating substrate) of the power semiconductor SW unit cell are given to the extended one-dimensional thermal conduction model, and the steady-state thermal capacitance Cₙ (unit: J/K) and the steady-state thermal resistance Rₙ (unit: K/W) of each layer are determined. Here, the subscript “n” represents a layer number, the power semiconductor SW chip is a first layer, the next die attach is a second layer, the chip metal conductor is a third layer, the heat transfer bonding material is a fourth layer, and the insulating substrate is a fifth layer in order.

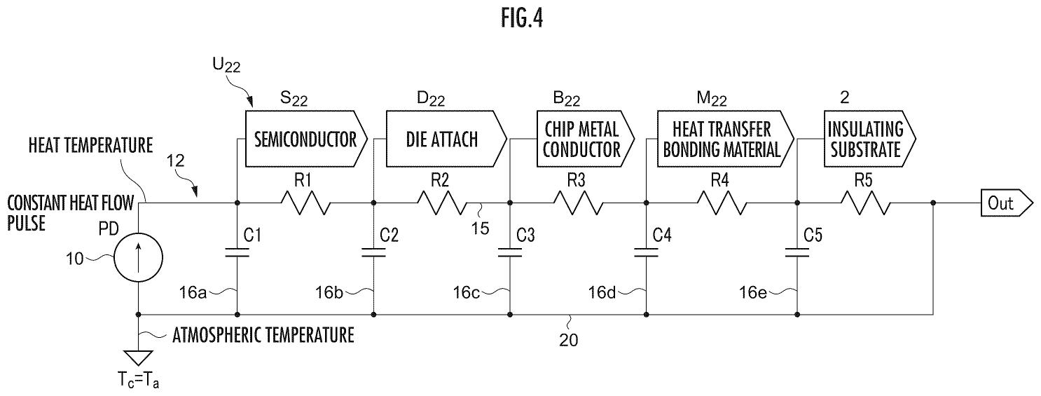

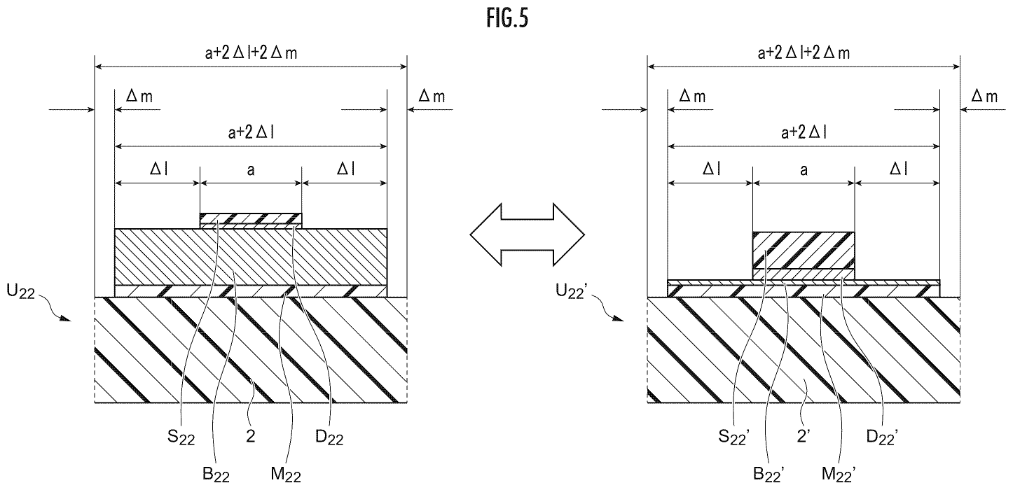

Once the steady-state thermal capacitance Cₙ and the steady-state thermal resistance Rₙ of each layer have been determined in this way, the steady-state thermal capacitance Cₙ and the steady-state thermal resistance Rₙ are substituted into each variable of the ladder thermal circuit model as shown in FIG. 4.

FIG. 4 is a thermal circuit diagram of the unit cell U₂₂. The power semiconductor SW chip S₂₂, the die attach D₂₂, the chip metal conductor B₂₂, the heat transfer bonding material Mᵢⱼ, and the insulating substrate 2 constitute a thermal circuit 12 that releases heat from a heat source 10 of the power semiconductor SW chip S₂₂ to the atmosphere. The thermal circuit 12 includes a first heat flow path 15 and second heat flow paths 16a, 16b, 16c, 16d, and 16e.

The first heat flow path 15 is composed of thermal resistance R1, R2, R3, R4, and R5 connected in series. The R1, R2, R3, R4, and R5 are the thermal resistances of the power semiconductor SW chip S₂₂, the die attach D₂₂, the chip metal conductor B₂₂, the heat transfer bonding material M₂₂, and the insulating substrate 2, respectively. The second heat flow paths 16a, 16b, 16c, 16d, and 16e respectively have the thermal capacitances C1, C2, C3, C4, and C5 branching from the first heat flow path 15 to the atmosphere on each surface side, the thermal capacitance C1, C2, C3, C4, and C5 branching at the each surface of the power semiconductor SW chip S₂₂, the die attach D₂₂, the chip metal conductor B₂₂, the heat transfer bonding material M₂₂, and the insulating substrate 2.

In FIG. 4, a ground heat flow path 20, which corresponds to the ground wire of an electrical circuit, corresponds to the surface of the unit cell U₂₂ exposed to the atmosphere and is at atmospheric temperature. The C1, C2, C3, C4, and C5 are the thermal capacitance of the power semiconductor SW chip S₂₂, the die attach D₂₂, the chip metal conductor B₂₂, the heat transfer bonding material M₂₂, and the insulating substrate 2, respectively.

With respect to the heat generation of the power semiconductor SW chip S₂₂ at the time of single-pulse current carrying in a predetermined ms range (for example, a range of 1 ms to 40 ms), regardless of whether or not heat dissipation through only the first heat flow path 15 is able to maintain the power semiconductor SW chip S₂₂ at or below the maximum rated temperature, the thermal impedance Z₂₂ of the thermal circuit 12 is set so that the power semiconductor SW chip S₂₂ is maintained at or below the maximum rated temperature by heat dissipation through the entire thermal circuit 12 of the first heat flow path 15 and the second heat flow paths 16a, 16b, 16c, 16d, and 16e.

It goes without saying that “regardless of whether or not heat dissipation through only the first heat flow path 15 is able to maintain the power semiconductor SW chip S₂₂ at or below the maximum rated temperature, the power semiconductor SW chip S₂₂ is set to be maintained at or below the maximum rated temperature by heat dissipation through the entire thermal circuit 12 of the first heat flow path 15 and the second heat flow paths 16a, 16b, 16c, 16d, and 16e” includes both “the case where the power semiconductor SW chip S₂₂ cannot be maintained at or below the maximum rated temperature by heat dissipation only through the first heat flow path 15” and “the case where the power semiconductor SW chip S₂₂ can be maintained at or below the maximum rated temperature by heat dissipation only through the first heat flow path 15”. In addition, even if “the power semiconductor SW chip S₂₂ can be maintained at or below the maximum rated temperature by heat dissipation only through the first heat flow path 15”, it is advantageous for making the unit cell Uᵢⱼ smaller and lowering the cost to set the heat capacitor C3 of the second heat flow path 16c such that more than half of the heat flow flowing from the power semiconductor SW chip S₂₂ to the chip metal conductor Bᵢⱼ via the first heat flow path 15 flows from the chip metal conductor Bᵢⱼ to the second heat flow path 16c.

Further, even if “the power semiconductor SW chip S₂₂ can be maintained at or below the maximum rated temperature by heat dissipation only through the first heat flow path 15”, by increasing the amount of heat dissipated through the second heat flow paths 16a, 16b, 16c, 16d, and 16e, the amount of heat dissipated through the first heat flow path 15 for maintaining the power semiconductor SW chip S₂₂ at or below the maximum rated temperature can be reduced, and the weight and cost of the single-pulse power semiconductor switching module can be reduced.

The maximum rated junction temperature T_{jMAX} is 75 to 125° C. for Si-IGBT, and 125 to 175° C. for SiC and GaN. In addition, the thermal impedance Z₂₂ is calculated from the thermal resistances R1, R2, R3, R4, R5 and the thermal capacitances C1, C2, C3, C4, C5 connected between the temperature of the heat source 10 and the atmospheric temperature.

In the thermal circuit 12 of FIG. 4, a step response Tⱼ(t) of a surface temperature Tⱼ of the power semiconductor SW chip S₂₂ when the surface of the power semiconductor SW chip S₂₂ is heated from time zero with a constant power PD (unit: W) is obtained by calculation. The following relationship (Equation 1) holds between Tⱼ and Z_{j-c} at any time t and Joule heat generation PD (constant, unit: W) of the power semiconductor SW chip. Therefore, by dividing each point of the Tⱼ(t) curve by PD, the transient thermal impedance characteristic Z_{j-c}(t) is obtained.

$${T}_{j} ( t ) = {Z}_{j - c} ( t ) \times PD \qquad ( Equation 1 )$$

### Example 1

Example 1 is an example of a single-pulse PSM equipped with a SiC MOSFET (chip size 4.8×4.8 mm 2) as the power semiconductor SW chip Sᵢⱼ of the unit cell Uᵢⱼ. The die attach Dᵢⱼ is Sn—Ag—Cu based SAC304 solder, the chip metal conductor Bᵢⱼ is pure Cu, the heat transfer bonding material Mᵢⱼ is a silicone-based thermally conductive sheet, and the insulating substrate 2 is an alumina plate. This material structure is the same in Comparative Examples 1-1 and 1-2 for comparison.

The thickness of Sᵢⱼ was 0.15 mm, the thickness of Dᵢⱼ was 0.02 mm, and the thickness of Bᵢⱼ was 3 mm. In addition, similarly, in accordance with the description of the present invention, the length of one side of Bᵢⱼ was 13.5 mm (Δl=4.1 mm). On the other hand, considering the single-pulse PSM prevalent in the market, the thickness of Sᵢⱼ′ in Comparative Examples 1-1 and 1-2 was 0.35 mm, the thickness of Dᵢⱼ′ was 0.1 mm, and the thickness of Bᵢⱼ′ was 0.3 mm. The length of one side of Bᵢⱼ′ was 13.5 mm (Δl=4.1 mm), which is the same as Bᵢⱼ.

The dimensions of the heat transfer bonding material Mᵢⱼ and the insulating substrate 2 are the same in Example 1 and Comparative Example 1-1, the thickness of the heat transfer bonding material Mᵢⱼ was 0.1 mm, one side was 13.5 mm, and the thickness of the insulating substrate 2 was 5 mm, and one side was 14.8 mm. In Comparative Example 1-2, the thickness of the insulating substrate 2 was made thinner than Comparative Example 1-1 to 3 mm in order to lower the steady-state thermal resistance R_{j-c} in accordance with the conventional thermal design method. Other values are the same as in Comparative Example 1-1.

FIG. 5 shows the vertical and horizontal dimensions of the PSM of Example 1 and the unit cells of Comparative Examples 1-1 and 1-2 (in FIG. 5, the subscript ij is 22). a is the length of one side of the power semiconductor chip Sᵢⱼ (and Sᵢⱼ′), here α=4.8 mm, and Δl is the distance between the outer edge of Sᵢⱼ (and Sᵢⱼ′) and the outer edge of the chip metal conductor Bᵢⱼ (and Bᵢⱼ′), here Δl=4.1 mm. Δm is the distance between the outer edge of the chip metal conductor Bᵢⱼ (and Bᵢⱼ′) and the outer edge of the unit cell Uᵢⱼ (and Uᵢⱼ′), and here, Δm=0.9 mm. 2Δm, which is twice Δm, corresponds to the insulation distance between the chip metal conductor Bᵢⱼ (and Bᵢⱼ′) and the adjacent chip metal conductor Bi (j+1) (and Bᵢⱼ+1)′) on the right in the figure.

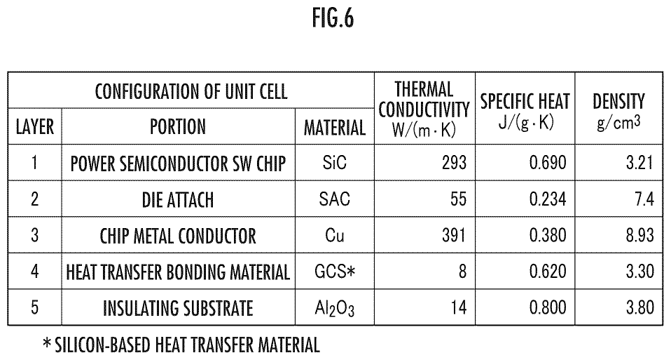

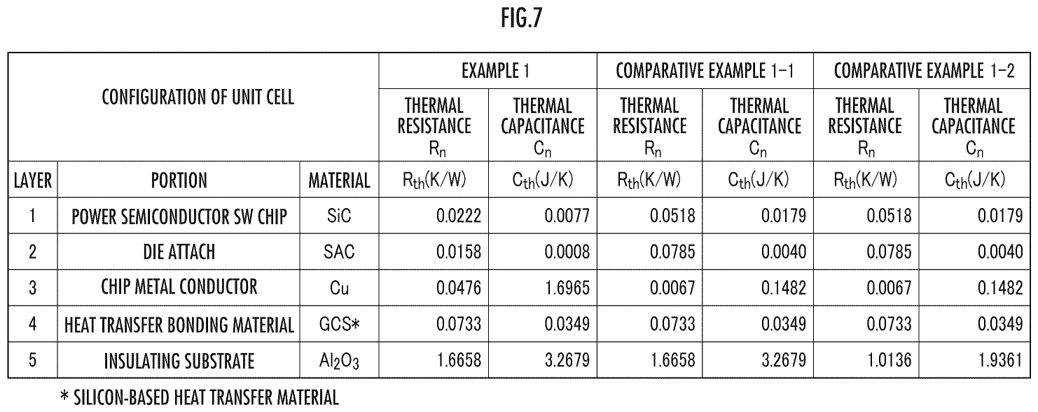

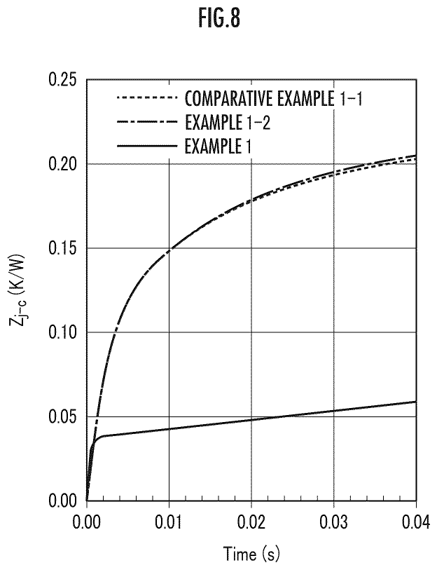

Regarding the structure shown in FIG. 5, in order to reduce the size and cost of the unit cell Uᵢⱼ, the relationship between the characteristics of Example 1 with respect to Comparative Examples 1-1 and 1-2 and the thermal circuit diagram of FIG. 4 is as follows: (a) thermal resistance R1 and R2 (FIG. 4) of the power semiconductor chip Sᵢⱼ and the die attach Dᵢⱼ were reduced, and heat flow is quickly transported to the chip metal conductor Bᵢⱼ below via the first heat flow path 15, (b) this heat flow coming from the power semiconductor chip Sᵢⱼ and die attach Dᵢⱼ was quickly dissipated (actually, heat stored) via the thermal capacitance C3 of the chip metal conductor Bᵢⱼ, that is, the second heat flow path 16c, and for this reason, the thermal capacitance of C3 was increased. The table in FIG. 6 shows the thermophysical constants of the materials of each portion used in Example 1 and Comparative Examples 1-1 and 1-2. When these thermophysical constants and the dimensions (thickness and length and width) of each portion are given to an extended one-dimensional thermal conduction model, the values of the steady-state thermal capacitance Cₙ and the steady-state thermal resistance Rₙ of each part can be obtained as shown in the table in FIG. 7.

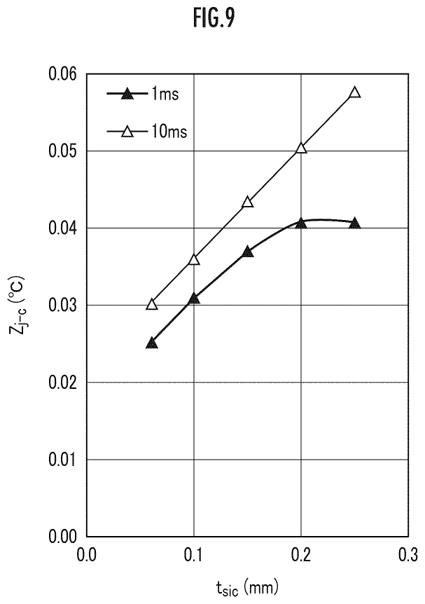

Numerical calculations were performed by substituting these values into the thermal circuit model of FIG. 4, and the graph of FIG. 8 is the result of simulating the transient thermal impedance characteristic Z_{j-c}(t) in the ms range. The horizontal axis represents the heating time (unit: s). The solid line in the graph is the transient thermal impedance characteristic of Example 1, and the broken line and the dashed line are the transient thermal impedance characteristics of Comparative Examples 1-1 and 1-2, respectively. The transient thermal impedance characteristics of Comparative Example 1-1 and Comparative Example 1-2 match to such an extent that it is difficult to visually recognize the transient thermal impedance characteristics up to around 30 ms.

It can be seen that in a time range of 1 ms or more, the transient thermal impedance Z_{j-c} of Example 1 is significantly reduced compared to Comparative Examples 1-1 and 1-2. For example, when compared at the time of 10 ms, in Comparative Example 1-1, Z_{j-c}=0.149 K/W, and also in Comparative Example 1-2, Z_{j-c}=0.149 K/W, whereas in Example 1 has Z_{j-c}=0.043 K/W, it can be seen that the present invention reduced the transient thermal impedance to ⅓ or less of the conventional value. As described above, it can be said that Example 1 has solved the first problem that “reduction of transient thermal impedance in the ms range is insufficient”.

Here, referring to the above (Equation 1), the fact that the transient thermal impedance Z_{j-c} can be reduced to ⅓ means that even if the Joule heat generation of the power semiconductor SW chip Sᵢⱼ is tripled, the same maximum rated surface temperature T_{jMAX} of the power semiconductor SW chip can be maintained. Considering this knowledge and the fact that the Joule heat generation of the power semiconductor SW chip Sᵢⱼ is expressed as the product of a load current I flowing through Sᵢⱼ and an applied voltage V, this means that in Example 1, a larger load current can be passed than in Comparative Example 1-1, in other words, the current density can be increased even if the power semiconductor SW chip has the same chip area.

When the on-resistance of a MOSFET is Ron, the Joule heat generation is I²Ron, so being able to triple the heat generation means that the load current can be increased by V3 times (73% increase). That is, it can be said that Example 1 also solves the second problem that “chip current density cannot be increased”.

As mentioned above, since the transient thermal impedance has decreased and the chip current density has increased, it is possible to reduce the number of power semiconductor SW chips or the area of power semiconductor SW chips, and with this reduction, the area of the unit cell can be reduced, thereby achieving downsizing and cost reduction of the PSM. That is, it can be said that Example 1 has solved the third problem that “downsizing and low cost of the PSM cannot be achieved”.

In the conventional single-pulse PSM thermal design, it was considered that reducing the steady-state thermal resistance R_{j-c} would lead to reducing the transient thermal impedance Z_{j-c}(t) in the ms range. Here, when comparing the steady-state thermal resistance R_{j-c} of Example 1 and Comparative Example 1-2, since R_{j-c} is the sum of the steady-state thermal resistance Rₙ of each layer from the front surface of the power semiconductor SW chip to the back surface of the insulating substrate, it can be seen that when adding up the Rₙ of each layer by referring to FIG. 7, in Example 1, R_{j-c}=1.825 K/W, in Comparative Example 1-2, R_{j-c}=1.224 K/W, and Comparative Example 1-2 provides a lower steady-state thermal resistance. According to the conventional thermal design guideline, Comparative Example 1-2 is supposed to provide a lower Z_{j-c} even in the ms range, but actually, as mentioned above, the present invention, which exhibits a higher steady-state thermal resistance, provides a much lower Z_{j-c}. This result can be said to point out the error or limitation of the conventional single-pulse PSM thermal design guideline.

Now that the description of the effects of the single-pulse PSM of Example 1 of the present invention has been ended, and it will be mentioned on what basis the thickness of each layer of the power semiconductor SW chip Sᵢⱼ, the die attach Dᵢⱼ, the chip metal conductor Bᵢⱼ, and the planar dimension a+2Δl (b+2Δl) of the chip metal conductor Bᵢⱼ were determined.

First, in order to explore the influence of the thickness t_{SiC} of the power semiconductor SW chip (SiC-MOSFET) Sᵢⱼ on the single-pulse PSM transient thermal impedance Z_{j-c} in the ms range, by changing the value of t_{SiC}, it was simulated how the transient thermal impedance characteristic Z_{j-c}(t) changes. The thickness and length and width of the portions other than t_{SiC} are all the same as those of Example 1 described above.

In order to understand the change in Z_{j-c}(t) intuitively and quantitatively, focus will be given to the change in Z_{j-c} between 1 ms and 10 ms. FIG. 9 plots Z_{j-c} (1 ms) and Z_{j-c} (10) ms) as a function of t_{SiC}. From this result, it is better to make t_{SiC} as thin as possible in order to reduce Z_{j-c} around 10 ms, but in order to reduce Z_{j-c} around 1 ms as well, it is concluded that t_{SiC} is desirably at least 0.2 mm or less at which the drop begins, and preferably 0.15 mm or less at which the drop actually occurs. As described above, the lower limit of reduction is the thickness of the effective device layer of the power semiconductor SW chip Sᵢⱼ.

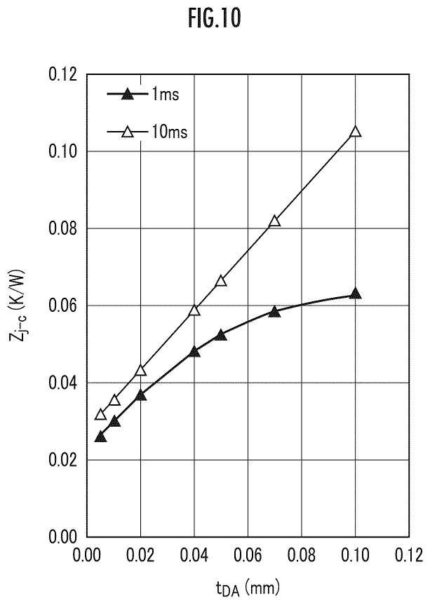

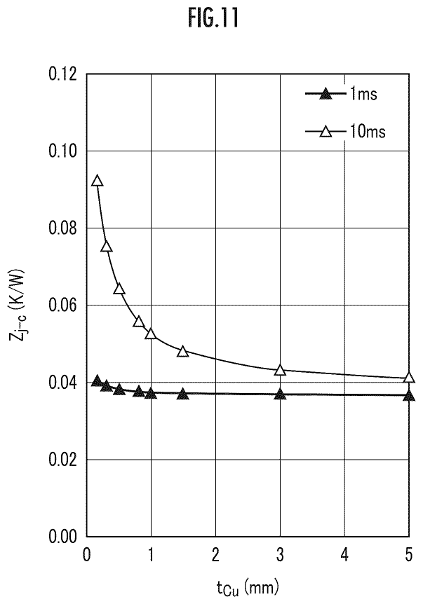

Similarly, the influence of the thickness t_{DA} of the die attach (solder SAC 304) Dᵢⱼ on the single-pulse PSM transient thermal impedance Z_{j-c} in the ms range was simulated. The thickness and length and width of the portions other than t_{DA} are all the same as those of Example 1 described above. FIG. 10 plots the relationship between the transient thermal impedance Z_{j-c} and t_{DA} for 1 ms and 10 ms.

It is concluded that in order to reduce Z_{j-c} around 10 ms, it is better to make t_{DA} as thin as possible. However, uniformly reducing Z_{j-c} in the range of 1 ms to 10 ms is advantageous in terms of practical marketability. In this way, if attention is paid to the change in Z_{j-c} for 1 ms, it can be seen that the reduction in Z_{j-c} for 1 ms becomes noticeable from around t_{DA}=0.05 mm, and decreases almost linearly from around t_{DA}=0.02 mm.

From this result, it is concluded that the thickness of the die attach is preferably at most 0.05 mm or less, and more preferably 0.02 mm or less. Further, the lower limit of the thickness of the die attach is 0.005 mm. The reason is that 0.005 mm is the limit (lower limit) in any die attach of (a) soldering by laying solder preforms (solder shaped like cushions) manufactured by rolling and punching and (b) soldering by printing and applying a solder paste on a screen and placing a semiconductor chip on the solder paste.

In addition, the influence of the thickness t_{Cu} of the chip metal conductor (Cu) Bᵢⱼ or the outer edge increment Δl_{Cu} for the power semiconductor SW chip on the single-pulse PSM transient thermal impedance Z_{j-c} were simulated and investigated in the same manner. Only t_{Cu} or Δl_{Cu} is changed, and the thicknesses and lengths and widths of other portions are all the same as those of Example 1.

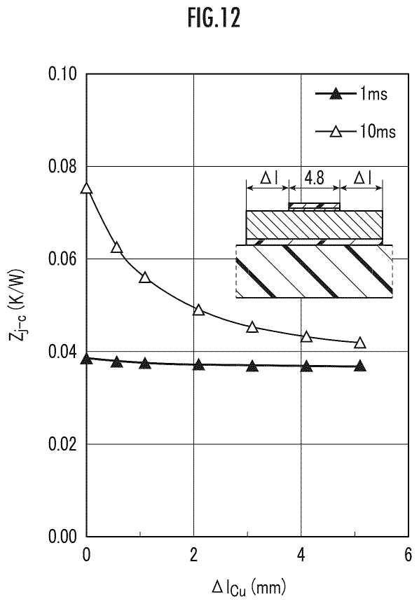

FIG. 11 shows the relationship between the transient thermal impedance Z_{j-c} for 1 ms and 10 ms and the thickness t_{Cu} of the chip metal conductor (Cu) Bᵢⱼ. The outer edge increment was Δl_{Cu}=4.1 mm (13 mm in terms of the length of one side of the chip metal conductor). It can be seen that increasing t_{Cu} has little effect on reducing Z_{j-c} for 1 ms, but has a tremendous effect on reducing Z_{j-c} around 10 ms. When t_{Cu} is 0.8 mm or more, a remarkable reduction effect of Z_{j-c} is observed, and when t_{Cu} exceeds 5 mm, there is a clear tendency for the reduction effect to be saturated. It can be seen that the reduction effect is particularly high in the range of 1.5 mm≤t_{Cu}≤3 mm. Thus, it is concluded that the thickness of the Cu electrode is preferably in the range of at least 0.8 mm<t_{Cu}<5 mm, and more preferably in a range of 1.5 mm≤t≤3 mm.

FIG. 12 shows the relationship between the transient thermal impedance Z_{j-c} for 1 ms and 10 ms and the outer edge increment Δl_{Cu} of the chip metal conductor (Cu) Bᵢⱼ. The thickness of the chip metal conductor (Cu) Bᵢⱼ was t_{Cu}=3 mm. As in the case of t_{Cu}, it can be seen that increasing Δl_{Cu} has little effect on reducing Z_{j-c} around 1 ms, but has a tremendous effect on reducing Z_{j-c} around 10 ms. A remarkable Z_{j-c} reduction effect is observed up to Δl_{Cu} of 2.1 mm, and when Δl_{Cu} exceeds 5.1 mm, there is a clear tendency for the reduction effect to become saturated. It can be seen that the reduction effect is particularly high in the range of 3.1 mm≤Δl_{Cu}≤4.1 mm. Thus, it is concluded that the Cu electrode thickness is preferably at least in the range of 2.1 mm<Δl_{Cu}<5.1 mm, and more preferably in a range of 3.1 mm≤Δl_{Cu}≤4.1 mm.

It has been found that the relationship between the transient thermal impedance Z_{j-c} and the power semiconductor SW chip, the relationship between Z_{j-c} and the thickness of the die-attach, and the relationship between Z_{j-c} and the thickness and the outer edge increment of the chip metal conductor, which were confirmed in FIGS. 9 to 12, are similarly confirmed not only in SiC-MOSFETs but also in other power semiconductor SW modules, although the degree of the relationships is slightly different.

### Example 2

The single-pulse PSM of Example 2 is a PSM that has a GaN power semiconductor SW chip, which has a higher yield strength and a slightly lower thermal conductivity than SiC, in the unit cell. The power device chip to be considered is a vertical MOSFET chip with a side of 4.8 mm formed on a GaN single crystal substrate, but may also be a bipolar transistor chip or a Schottky diode chip.

The thickness of the vertical GaN-MOSFET chip is set to 0.15 mm, which is the minimum thickness that can be manufactured by using today's cutting-edge power GaN semiconductor device manufacturing technology and in accordance with the spirit of the present invention described above. The configuration of the other parts of the PSM unit cell except for the power semiconductor SW chip is the same as in Example 1 (FIGS. 3 and 5).

In Comparative Example 2 to be compared with Example 2, it is assumed that a GaN power semiconductor SW chip manufactured with a thickness of 0.35 mm (=normal thickness) is used, and the configuration of the other parts except for the power semiconductor SW chip is the same as in Comparative Example 1-1 (FIGS. 10 and 5).

The thermophysical property values of the GaN single crystal necessary for simulating the transient thermal impedance characteristic Z_{j-c}(t) are as follows. Thermal conductivity: 168 W/(m·K), specific heat: 0.459 J/(g·K), density: 6.15 g/cm³.

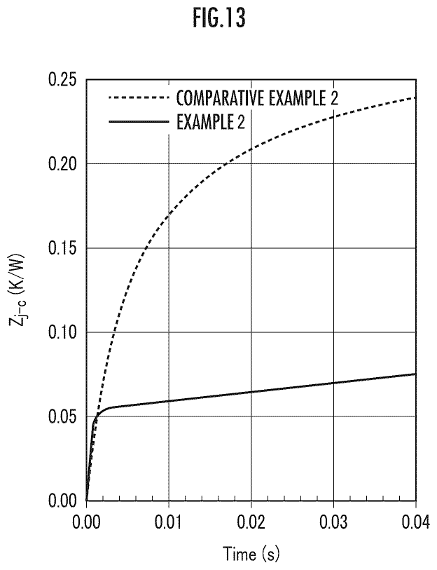

FIG. 13 shows the transient thermal impedance characteristics Z_{j-c}(t) of Example 2 and Comparative Example 2 in the ms range. The solid line in the graph is the transient thermal impedance characteristic of (the unit cell of) Example 2, and the broken line is the transient thermal impedance characteristic of (the unit cell of) Comparative Example 2.

It can be seen that in a time range of 1 ms or more, the transient thermal impedance Z_{j-c} of Example 2 is significantly reduced compared to the PSM of Comparative Example 2. For example, when compared at the time of 10 ms, since the PSM of Comparative Example 2 has Z_{j-c}=0.1695 K/W, whereas the PSM of Example 1 has Z_{j-c}=0.0597 K/W, it can be seen that the present invention reduced the transient thermal impedance to ⅓ or less.

Since the transient thermal impedance was reduced to less than ⅓, it can be said that Example 2 has solved the first problem that “reduction of transient thermal impedance in the ms range is insufficient”.

By reducing this transient thermal impedance to ⅓ or less, the load current of the GaN-MOSFET can be increased by about √3 times (73%) compared to the PSM of Comparative Example 2, therefore, it can be said that the second embodiment also solves the second problem that “the chip current density cannot be increased”.

Since the chip current density is increased as compared with Comparative Example 2, not only is it possible to reduce the number of GaN-MOSFET chips mounted on the PSM or the area of the GaN-MOSFET chips, but this reduction also achieves a reduction in the area of the unit cell, thereby achieving downsizing and cost reduction of the PSM. In this way, it can be said that Example 2 has solved the third problem that “downsizing and low cost of the PSM cannot be achieved”.

### Example 3

The single-pulse PSM of Example 3 is a single-pulse PSM using Si-IGBT, which is most commonly used as a power semiconductor SW today. An example using a Si-IGBT chip of 4.8 mm square on each side will be described, but this is for convenience of description, and the result will not change regardless of the size of the Si-IGBT. Further, the type of device may be a MOSFET, a bipolar transistor, or a pn diode chip.

Regarding Si-IGBT chips, since ultra-thin chips with a thickness of 0.06 mm are commercially available, the comparison will be made assuming that both the single-pulse PSMs of Example 3 and Comparative Example 3 used for comparison are equipped with ultra-thin chips.

The other configurations of Example 3 are the same as those of Example 1 (FIGS. 3 and 5). Further, the other configurations of Comparative Example 3 are the same as those of Comparative Example 1-1 (FIGS. and 5).

The thermophysical property values of the Si single crystal necessary for simulating the transient thermal impedance characteristic Z_{j-c}(t) are as follows. Thermal conductivity: 73 W/(m·K), specific heat: 0.784 J/(g· K), density: 2.33 g/cm³.

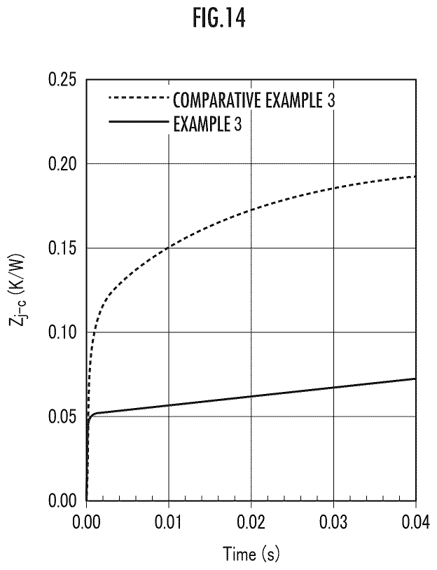

FIG. 14 shows the transient thermal impedance characteristics Z_{j-c}(t) of Example 3 and Comparative Example 3 in the ms range. The solid line in the graph is the transient thermal impedance characteristic of Example 3, and the broken line is the transient thermal impedance characteristic of Comparative Example 3.

It can be seen that in a time range of 1 ms or more, the transient thermal impedance Z_{j-c} of the PSM of Example 3 is significantly reduced compared to the PSM of Comparative Example 3. For example, when compared at the time of 10 ms, since the PSM of Comparative Example 3 has Z_{j-c}=0.1503 K/W, whereas the PSM of Example 3 has Z_{j-c}=0.0571 K/W, it can be seen that the present invention reduced the transient thermal impedance to about 38%. This reduction was achieved by optimizing the thickness of the die attach and the thickness and size of the chip metal plate.

Since the transient thermal impedance was able to be reduced to 38%, it can be said that Example 3 has solved the first problem that “reduction of transient thermal impedance in the ms range is insufficient”.

Since it is expected that the load current of the Si-IGBT can be increased by about 62% compared to the PSM of Comparative Example 2 by reducing the transient thermal impedance by 38%, it can be said that Example 3 also has solved the second problem that “the chip current density cannot be increased”.

In Example 3, since the chip current density is increased as compared with Comparative Example 3, not only is it possible to reduce the number of Si-IGBT chips mounted on the PSM or the area of the Si-IGBT chips, but this reduction also achieves a reduction in the area of the unit cell, thereby achieving the downsizing and cost reduction of the PSM. In this way, it can be said that Example 3 has solved the third problem that “downsizing and low cost of the PSM cannot be achieved”.

### Example 4

The vertical and horizontal dimensions of the power semiconductor SW chips Sᵢⱼ of Examples 1 to 3 were all 4.8 mm. The dimensions of the power semiconductor SW chip Sᵢⱼ are not limited to this size, and Sᵢⱼ having any size can be applied. Example 4 is a case in which the dimensions (FIG. 5) of the SiC-MOSFET (Sᵢⱼ) of Example 1 are reduced to α=3.0 mm. The dimension of Sᵢⱼ′ in Comparative Example 4 is also 3.0 mm. The values of Δl and Δm are the same as in Example 1, Δl=4.1 mm and Δm=0.9 mm. The composition, thermophysical properties, and thickness of each PSM material were the same as in Example 1.

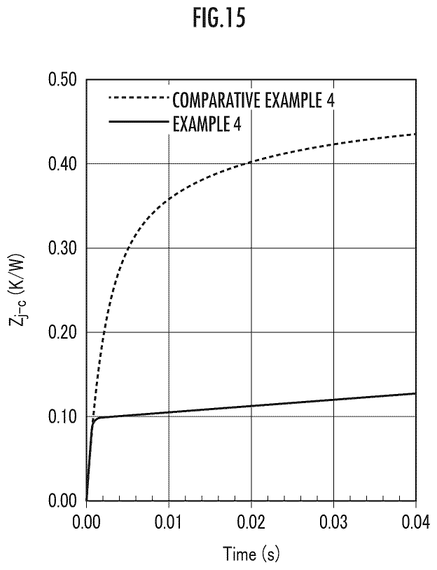

FIG. 15 shows the transient thermal impedance characteristics Z_{j-c}(t) of Example 4 and Comparative Example 4 in the ms range. In the graph, the solid line represents the transient thermal impedance characteristic of the PSM (unit cell) of Example 4, and the broken line represents the transient thermal impedance characteristic of the PSM (unit cell) of Comparative Example 4.

It can be seen that the transient thermal impedance Z_{j-c} of the PSM of Example 4 is significantly reduced compared to the PSM of Comparative Example 3 in a time range of 1 ms or more. For example, when compared at the time of 10 ms, since the PSM of Comparative Example 3 has Z_{j-c}=0.3565 K/W, whereas the PSM of Example 1 has Z_{j-c}=0.1044 K/W, it can be seen that the present invention reduced the transient thermal impedance to about 29%.

Since the transient thermal impedance was able to be reduced to about 29%, it can be said that Example 4 has solved the first problem that “Reduction of transient thermal impedance in the ms range is insufficient”.

With this transient thermal impedance of about 29%, it is expected that the load current of the SiC-MOSFET can be increased by about 71% compared to the PSM of Comparative Example 4. Therefore, it can be said that Example 4 also has solved the second problem that “the chip current density cannot be increased”.

Since the chip current density is increased as compared with Comparative Example 4, not only is it possible to reduce the number of SiC-MOSFET chips mounted on the PSM or the area of the SiC-MOSFET chips, but this reduction achieves a reduction in the area of the unit cell, thereby achieving downsizing and cost reduction of the PSM. In this way, it can be said that Example 4 has solved the third creative issue of “downsizing and low cost of the PSM cannot be achieved”.

### Example 5

Example 5 is a case in which the dimension (α=4.8 mm) of the power semiconductor chip Sᵢⱼ of Example 1 is increased. Here, α=10 mm. The dimension of Sᵢⱼij′ of Comparative Example 5 was also α=10 mm. The values of Δl and Δm are the same as in Example 1, Δl=4.1 mm and Δm=0.9 mm. The configuration, thermophysical properties, and thickness of each PSM material are the same as in Example 1.

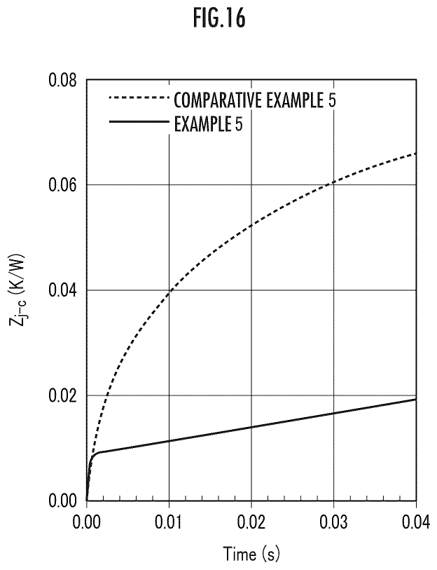

FIG. 16 shows the transient thermal impedance characteristics Z_{j-c}(t) of Example 5 and Comparative Example 5 in the ms range. The solid line is the transient thermal impedance characteristic of (the unit cell of) the PSM of Example 5, and the broken line is the transient thermal impedance characteristic of (the unit cell of) the PSM of Comparative Example 5.

It can be seen that in a time range of 1 ms or more, the transient thermal impedance Z_{j-c} of the PSM of Example 5 is significantly reduced compared to the PSM of Comparative Example 5. When compared at the time of 10 ms, since in the PSM of Comparative Example 5, Z_{j-c}=0.0393 K/W, whereas in the PSM of Example 5, Z_{j-c}=0.0114 K/W, it can be seen that the transient thermal impedance was reduced to about 29% in Example 5.

Since the transient thermal impedance was reduced to about 29%, it can be said that Example 5 has solved the first problem that reduction of transient thermal impedance in the ms range is insufficient.

By reducing the transient thermal impedance by about 29%, it is expected that the load current of the SiC-MOSFET can be increased by about 71% compared to the PSM of Comparative Example 4. Therefore, it can be said that Example 5 also solves the second problem that “chip current density cannot be increased”.

In Example 5, since the chip current density is increased as compared with Comparative Example 5, not only is it possible to reduce the number of SiC-MOSFET chips mounted on the PSM or the area of the SiC-MOSFET chips, but this reduction achieves a reduction in the area of the unit cell, thereby achieving downsizing and cost reduction of the PSM. In this way, it can be said that Example 5 has solved the third creative issue of “downsizing and low cost of the PSM cannot be achieved”.

### (Application Example of Short-Pulse PSM)

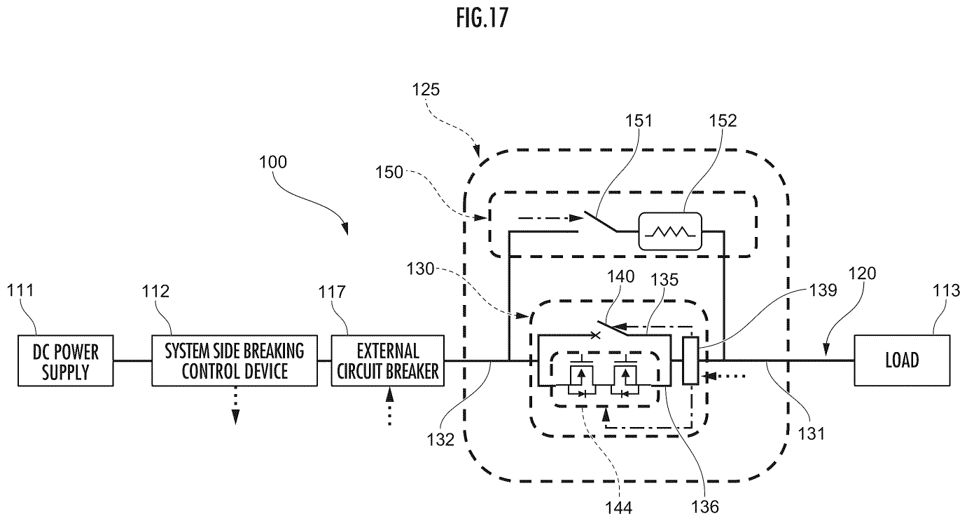

FIG. 17 is a schematic view of a DC power supply system 100 as an application example of a hybrid DC circuit breaker 125 equipped with the single-pulse PSM 1 of FIG. 1. The single-pulse PSM 1 in FIG. 1 is implemented as a semiconductor SW section 144 in the DC power supply system 100.

The DC power supply system 100 includes a DC power supply 111, an equipment-side breaking control device 112, an external circuit breaker 117, a DC circuit breaker 125, and a load 113 in order on a main current path 120 in the direction of flow of DC current.

The DC power supply system 100 is used, for example, for offshore wind power generation. The external circuit breaker 117 can be omitted.

The hybrid DC circuit breaker 125 includes a main circuit 130 and a sub-circuit 150 that are connected in parallel to each other. The sub-circuit 150 can be omitted.

The main circuit 130 includes a parallel connection portion composed of a first current path 135 and a second current path 136 that are connected in parallel to each other, and a one-side main current path 131 and an other-side main current path 132 on one side and the other side of the parallel connection portion, respectively. The one-side main current path 131 and the other-side main current path 132 constitute the main current path 120 in the hybrid DC circuit breaker 125.

The switch control section 139 is provided in the one-side main current path 131 and detects the current value of the main current flowing through the one-side main current path 131 (hereinafter, also referred to as “main current value i”) and the time differential value of the main current value i (hereinafter, also referred to as “time differential value”). The switch control section 139 also receives a command signal (indicated by a dotted line with an arrow in the figure) from the equipment-side cut-off control device 112. The switch control section 139 generates a switching signal for switching the switching positions of the mechanical SW section 140 and the semiconductor SW section 144 between on and off based on the main current value i, the time differential value j, and the command signal, and outputs the switching signal to the mechanical SW section 140 and the semiconductor SW section 144 (indicated by a dashed line with an arrow in the figure).

Mechanical SW sections such as the mechanical SW section 140 belong to so-called low resistance switches. The semiconductor SW section 144 is composed of, for example, two field effect transistors (FETs) connected in series with the sources facing each other.

The sub-circuit 150 includes a mechanical switch 151 and a resistor 152 that are connected in series, and are connected at both ends to the main current path 131 on one side and the main current path 132 on the other side, respectively.

To roughly describe the operation of this DC power supply system 100, during normal operation of the DC power supply system 100, the mechanical SW section 140 is kept on state, and the main DC current output from the external circuit breaker 117 is supplied to the load 113 via the first current path 135. In this DC power supply system 100, the main current value i during normal operation of the DC power supply system 100 is assumed to be approximately 500 A. With the occurrence of an abnormal state in the DC power supply system 100, the main current value i rapidly increases. The maximum increase in abnormal current may be 10 kA or more.

When an abnormal state occurs in the DC power supply system 100, the main current value i and/or the time differential value j increase, and the main current value i≥α and/or the time differential value j≥β. If it is determined that the main current value i≥α and/or the time differential value j≥β, the switch control section 139 outputs a switching signal to the semiconductor SW section 144 to switch the semiconductor SW section 144 from off state to on state, and the semiconductor SW section 144 switches from off state to on state.

The switch control section 139 then outputs a switching signal to the mechanical SW section 140 to switch the mechanical SW section 140 from on state to off state. At this time, the on-voltage of the semiconductor SW section 144, that is, the voltage across the mechanical SW section 140, has a value that does not reach an arc generation voltage. As a result, the mechanical SW section 140 is smoothly turned off without causing arc discharge.

### Modification Example

In the thermal circuit diagram (FIG. 4) of the embodiment, in the unit cell U₂₂, the lower surface side includes the back surface side of the insulating substrate 2. In the thermal circuit of the present invention, in the single-pulse PSM 1, the lower surface side of each unit cell Uᵢⱼ may include at least the back surface side of the chip metal conductor Bᵢⱼ.

Although the single-pulse PSM1 has been described in the embodiment, the power semiconductor switching module of the present invention is not limited to being exclusively used as the single-pulse PSM 1, and the same PSM may serve as both a single-pulse PSM and a non-single-pulse PSM.

In each example, specific numerical values are presented, but it goes without saying that it is within the common sense of those skilled in the art in the semiconductor technology field that within a range of +3% for each specific numerical value, the same effect as each specific numerical value of the corresponding example is achieved.

### DESCRIPTION OF REFERENCE NUMERALS

1: single-pulse energization power semiconductor switching module
Uᵢⱼ: power semiconductor SW unit cell (unit cell)
Sᵢⱼ: power semiconductor SW chip
Dᵢⱼ: die attach
Bᵢⱼ: chip metal conductor
Mᵢⱼ: heat transfer bonding material
2: insulating substrate
B_{P}: P-terminal metal conductor
B_{N}: N-terminal metal conductor
B_{Gj}: control terminal metal conductor
B_{Sj}: control terminal metal conductor
Iᵢⱼ: main circuit interconnect (thick Al bonding wire)
I_{Pj}: P-terminal metal conductor connection main circuit interconnect (thick Al bonding wire)
I_{Gj}: signal line interconnect (thin Al bonding wire)
I_{Sj}: signal line interconnect (thin Al bonding wire)

1. A power semiconductor switching module comprising:
an insulating substrate;
a chip metal conductor stacked on an upper surface side of the insulating substrate;
a plurality of power semiconductor SW chips; and
a die attach interposed between the chip metal conductor and each of the power semiconductor SW chips, wherein
each of the power semiconductor SW chips, the die attach under a lower surface side of the power semiconductor SW chip, and the chip metal conductor under a lower side of the die attach constitutes a thermal circuit that releases heat from a heat source of each of the power semiconductors SW chip to the atmosphere,
each thermal circuit includes a first heat flow path composed of thermal resistances from each heat source to a lower surface of the chip metal conductor, and a second heat flow path composed of thermal capacitances branching from the first heat flow path to the atmosphere on each surface side, the thermal capacitances branching at a surface of each of the power semiconductor SW chips, the die attaches, and the chip metal conductors, and
with respect to heat generation of the power semiconductor SW chips at a time of single-pulse current-carrying in a predetermined ms range,
regardless of whether or not heat dissipation through only the first heat flow path is able to maintain the power semiconductor SW chips at or below a maximum rated temperature, a transient thermal impedance of the thermal circuit is set so that the power semiconductor SW chips are maintained at or below the maximum rated temperature by heat dissipation through the entire thermal circuit of the first heat flow path and the second heat flow path.

2. The power semiconductor switching module according to claim 1, wherein
the predetermined ms range is a range of 1 ms to 40 ms.

3. The power semiconductor switching module according to claim 1, wherein
a thickness of the power semiconductor SW chip is selected as a parameter for setting a thermal impedance of the thermal circuit.

4. The power semiconductor switching module according to claim 3, wherein
the thickness of the power semiconductor SW chip is at least larger than a thickness of a power semiconductor SW effective device layer and 0.2 mm or less.

5. The power semiconductor switching module according to claim 1, wherein
a thickness of the die attach is selected as a parameter for setting a thermal impedance of the thermal circuit.

6. The power semiconductor switching module according to claim 5, wherein
the thickness of the die attach is within a range of 0.005 mm to 0.05 mm.

7. The power semiconductor switching module according to claim 1, wherein
a thickness of the chip metal conductor and an amount of protrusion of the chip metal conductor outward from a lower surface of the die attach are selected as parameters for setting a thermal impedance of the thermal circuit.

8. The power semiconductor switching module according to claim 7, wherein
the thickness of the chip metal conductor is within a range of 0.8 mm to 5 mm, and when the amount of protrusion is Δl, Δl is in a range of 2.1 mm<Δl<5.1 mm.

9. The power semiconductor switching module according to claim 1, wherein
the transient thermal impedance of the thermal circuit is such that heat dissipation through only the first heat flow path is not able to maintain the power semiconductor SW chip at or below the maximum rated temperature.

10. The power semiconductor switching module according to claim 2, wherein
a thickness of the power semiconductor SW chip is selected as a parameter for setting a thermal impedance of the thermal circuit.

11. The power semiconductor switching module according to claim 10, wherein
the thickness of the power semiconductor SW chip is at least larger than a thickness of a power semiconductor SW effective device layer and 0.2 mm or less.
